(19) United States
(12) Patent Application Publication
(10) Pub. No.: US 2021/0104908 A1
(43) Pub. Date: Apr. 8, 2021

(54) Incorporation of high band-gap solar cells into screens of mobile electronic devices

(71) Applicant: Ariel Efrati, Jerusalem (IL)

(72) Inventor: Ariel Efrati, Jerusalem (IL)

(21) Appl. No.: 17/062,582

(22) Filed: Oct. 3, 2020

Related U.S. Application Data
(60) Provisional application No. 62/910,471, filed on Oct. 4, 2019.

(51) Int. Cl. H02J 7/35; H02S 10/40; H01L 27/30; H01L 51/42; H01L 51/44; H05K 5/00

(52) U.S. Cl. CPC H02J 7/35; H02S 10/40; H01L 27/302; H05K 5/0086; H01L 51/442; H01L 51/447; H05K 5/0017; H01L 51/426

(57) ABSTRACT

The current invention allows the solar charging of mobile electronic devices through substantially transparent screen-integrated photovoltaic cells. The current invention utilizes high energy-low wavelength light to produce electric power, through a high band-gap photovoltaic panel which is installed as part of the device's screen. This invention will allow prolonging the usage time of smartphones; laptop computers; tablets; e-readers, mobile phones, electronic watches, and more, without significant weight, volume, or cost addition.

### FIELD OF THE INVENTION

The present invention relates to the incorporation of high band gap solar cells into screens of mobile electronic devices such as smartphones.

### BACKGROUND OF THE INVENTION

Currently, most mobile electronic devices have to be recharged via connection to an electrical grid. Current smartphones' batteries are capable of powering up to 5000 mAh of charge, with a voltage of 3.7 V for lithium-ion batteries with graphite anodes, which supplies a total energy of 18.5 Wh. Such energy supply, for the regular practice of most users, is sufficient for a day or two. Additional operation time may be very valuable to the owner once the battery is fully discharged, when a conventional charging mechanism is not available. Extra-charging may be proved invaluable during emergency as well.

It should be noted that the spectral sensitivity of human visual perception of brightness decreases substantially towards the short wavelengths of the visible spectrum, especially under 450 nm. Nonetheless, the solar irradiance spectrum, even after being filtered by the atmosphere, maintains a power density illumination of ca. 4.7 mW/cm² of light under the wavelength of 400 nm. Similarly, the solar flux is ca. 10.9 mW/cm² of light under the wavelength of 450 nm, ca. 15.6 mW/cm² of light under the wavelength of 480 nm and ca. 18.7 mW/cm² of light under the wavelength of 500 nm (all integrated from AM1.5 G standard). It should also be noted that an extraction of even a few percent of these energy fluxes by the screen area would be a considerable source for recharging mobile devices such as cellular phones. In addition, it should be noted that glass and most conductive transparent materials usually have significant absorbance under the wavelength of about 350 nm. The power flux up to 350 nm is only ca. 1.4 mW/cm².

The incorporation of conventional solar panels into the back of mobile instruments, is a straightforward approach and was discussed in few prior art cases. Nonetheless, additional costs, additional weight and design issues, hinder the idea from manifesting into practical use. Additional prior art (as in: Chen, C. US 2011/0157034 A1), considered the utilization of conventional solar panels situated on the screen, between the light source of the screen and the observer. Solar cells such as silicon-based solar cells, which possess a low band gap of 1.14 eV, absorb light throughout the visible spectrum. Even a very thin layer of silicon, which absorbs only part of the light, would require an appropriate adjustment to the increase in projected light intensity. It should be noted that the screens of mobile devices are a major power-consuming component (Carroll, A. et al. USENIX annual technical conference. 14, (2010)). Since the power conversion efficiency of solar panels is limited to practical use of about 20%, significant energetic loss is expected when the screen is not under full sun irradiation conditions.

### SUMMARY OF THE INVENTION

It is therefore an object of the current invention to disclose a method to incorporate a high energy photon harvesting photovoltaic apparatus into cellular phone screens. Such solar cell is designed to be situated on top of the main light emitting layers of the screen and collect low wavelength UV and violet-blue light. Using this configuration, it will be possible to collect high-energy photons from sun radiation for the production of direct current, and the recharging of the batteries. Additionally, similar light, emitted from the screen itself, will be absorbed by the active layer of the solar cell as well, with minimum effect on the screen display properties. Another benefit of the current invention is the protection of the screen from sun damage through the collection of UV light on top of the screen, before it reaches the inner layers of the screen. Yet another benefit of the current design is the lightweight and low cost properties of the photovoltaic apparatus, intended for incorporation into the screen itself. In this case, the screen serves as a rigid substrate for the thin layers of the solar cell's constituents.

The incorporated solar cells consist of thin layers with different functionalities, which can be a part of the device's screen itself. Another key element of the solar cell is the low absorbance properties, of all of its layers, in the visible wavelengths above 500 nm and relatively high absorbance in the spectral region below wavelengths of 500 nm, preferably including high absorbance in the UVA (315-400 nm) and UVB (280-315 nm) regions. The family of high band gap solar cells includes three types of cells, using three different active materials. high band gap semiconducting materials, quantum dots and organic solar cells i.e. organic photovoltaics. Two additional transparent conductive layers will be applied as cathodic and anodic contacts, along with additional layers that promote the directionality of the current, such as electron/hole transport layers.

According to the current invention, the solar cell will be located below the top layer of the screen. For example, in LCD (liquid-crystal display) screens, the twisted nematic liquid crystal layer is usually located between two conductive transparent electrodes and two layers of polarizing filters. The top layer of the screen is usually transparent and conductive, as part of the touchscreen functionality. The solar cell will be situated further out from the liquid crystal layer, or the layers of another display method, towards the top surface of the screen. This configuration will be applied to all LCD technologies, such as: TN (twisted nematic), VA (vertical alignment), PVA (patterned vertical alignment) IPS (in plane switching), in addition to displays of different illumination methods such as QLED (quantum-dot light-emitting diode), MicroLED, AMOLED (active-matrix organic light-emitting diode) and related technologies as well. Similarly, OLED (organic light-emitting diode) screens are constructed with equivalent transparent and conductive layers on both sides of the organic material, as well as transparent layer on the top surface of the screen. The solar cell layers will be located between the organic material layer and the top surface. The conductive layers of the solar cells will be composed of transparent conductive materials such as: ITO (indium tin oxide), FTO (fluorine tin oxide), aluminum, gallium or indium-doped zinc oxide (AZO, GZO or IZO), conductive polymers such as PEDOT:PSS i.e. poly(3,4-ethylenedioxythiophene) polystyrene sulfonate, graphene and carbon nanotubes.

Inorganic semiconductor based solar cells will operate, according to the current invention, with a large band gap—over 2.48 eV which corresponds to 500 nm photon. In this way, visible light with wavelengths above 500 nm will be transmitted through the solar cell. Examples for such materials include, and are not limited to Cr₂O₃; MnO; CoO; TiO₂; NiO; As₂S₃; ZnSe; ZnS; ZnO; Ge₃N₄; WO₃; BCN; GaN; SrTiO₃; C₃N₄; Bi₂WO₆ and SiC, including all polymorphs and blends with band gaps larger than 2.58 eV. The application of the materials can be done through chemical deposition methods such as chemical solution deposition, chemical bath deposition, spin coating, dip coting, CVD (chemical vapor deposition) ALD (atomic layer deposition), or physical deposition methods such as sputtering, pulsed laser deposition and others. Additional selective HTM (hole transport materials such as PEDOT: PSS and spiro group derivatives) or ETL (electron transport layers such as compact or mesoporous TiO₂ layers) may be added (both or only one type) between the photoactive layer and the cathode/anode. These layers selectively allow only holes or electrons to pass through them and thus induce an anisotropic diffusion of charges under illumination. Quantum dots or nanorods composed of semiconducting materials may replace the bulk materials mentioned above. Due to the quantum size effect, it is possible to accurately tune a band gap to 2.58 eV or higher, and achieve the desired visible light absorbance. Thanks to this increase in band gap due to nano-confinement, it is possible to incorporate other semiconducting materials with smaller bulk band gaps as well as core-shell nanoparticles in order for the desired band gap to be achieved. Furthermore, the utilization of organic solar cell configuration is possible. While most light-absorbing donor molecules and polymers, traditionally used in organic solar cells, possess low band gaps (referring to the HOMO-LUMO difference), the use of high band gap substances is notable as well. For example, recent prior art (Garcias-Morales, C. et al. Molecules 22.10 (2017): 1607) demonstrated a bulk heterojunction organic solar cell which employs a donor of thieno[3,4-c]pyrrole-4,6-dione derivative and [6,6]-phenyl C71 butyric acid methyl ester (PC71BM) acceptor. A maximal absorbance at a wavelength of 433 nm and a band gap of 2.48 eV, equivalent to almost 500 nm wavelength light, were observed together with 2.32±0.28 power conversion efficiency. Thereby, the employment of light absorbing acceptor molecules and polymers in this invention is limited to substances with band gaps larger than 2.48 eV. Any tandem multi-junction combination of the previously mentioned solar cells is conceivable for the purpose of higher total power conversion efficiency.

It is a core purpose of the current invention to disclose a method to incorporate a high energy photon harvesting photovoltaic apparatus into mobile electronic devices such as smartphones; laptop computers; tablets; e-readers and mobile phones. These solar cells are incorporated into the screens of the devices, and are formulated according to the previously mentioned solar cell constructions. A key feature of the incorporated solar cells is substantial transparency in the visible wavelengths above 500 nm, which allow for regular functionality of the screen. The objective of this incorporation is to provide an alternative way to recharge the devices' batteries fully or partially.

Another object of the present invention is to provide a method to reduce UV light and high energy visible light emittance from the screens of cellular phones, tablets, and portable electronic devices which include a screen.

A specific example of the method is a smartphone comprising a screen which is composed of an LDC module assembly. On top of said assembly, a conductive ITO layer was deposited using CVD. A compact TiO₂ layer of 30 nm, acting as an ETL was then applied using chemical bath deposition with TiCl₄ solution. A photoactive silicon carbide (SiC) layer was later deposited by CVD method e.g. 200 nm thick layer. Using ALD, a conducive graphene layer was formed on top of the silicon carbide. Finally, conventional methods were applied to form the touch screen mechanism. Said anodic ITO layer and cathodic graphene layer are connected to the charging mechanism of the phone. The band gap of the SiC 6H(alpha) layer is about 3.05 eV and allows visible light above a wavelength of 407 nm to pass freely from the LCD assembly to the user. Photons under the wavelength of 407 nm will be absorbed by the solar cell at high percentage and generate power to recharge the battery of the smartphone.

More advantages, characteristics, features and operation methods of the current invention will emerge as a consequence of the following claims and the accompanying drawings. Similarly, the functionality of the parts and their combinations and elements of manufacture will be more noticeable as well. A brief description of the drawings appears next, and is followed by a detailed one and then the accompanying claims.

### BRIEF DESCRIPTION OF THE FIGURES

The believed key elements of the invention are provided below by way of example.

Substantial emphasis should be placed on the fact that the drawings are for illustration and clarification purposes only, and are not intended to be a definition of the limits of this invention.

FIG. 1 is an illustration of the detached layers of a mobile electronic device which comprises a high-energy-photon harvesting solar cell;

### DETAILED DESCRIPTION OF THE ILLUSTRATED EMBODIMENTS

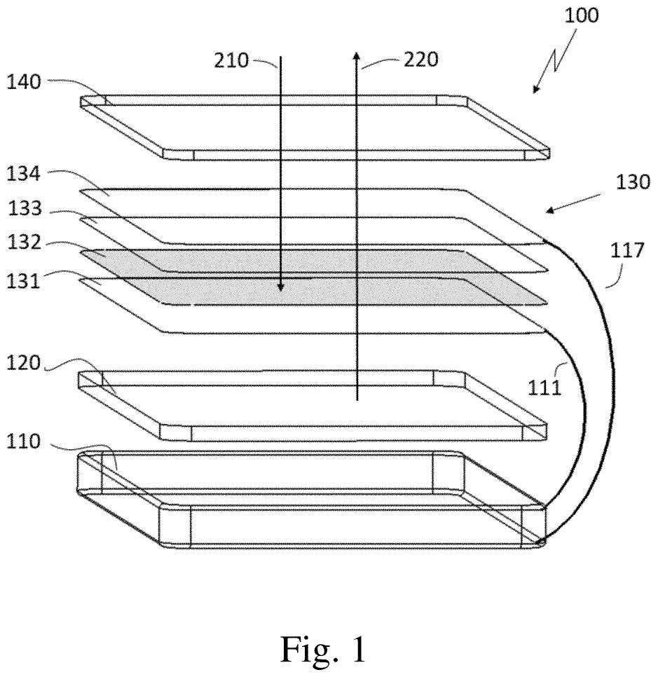

Reference is now made to FIG. 1, which demonstrates the integration of a high-energy-photon absorbance solar cell in a screen. Said integrated screen for a mobile device 100, is formed as a layered structure which includes a display module 120, a low wavelength absorbing solar cell 130, and a touchscreen module 140. The term “display module” refers to the chosen type of display system and its components, such as LCD, which includes backlight components, polarizing layers, liquid crystal layer etc. The solar cell component is situated between the display and touchscreen modules. This solar cell comprises an anode 134, which can be coated with an ETL 133 and a cathode 131, and may also include an HTM layer. The active layer 132 absorbs high-energy photons and is substantially transparent to visible light with wavelengths above 500 nm. This is a general description of the solar cell, and can represent cells with an active layer composed of a semiconductor, quantum confined structures, organic absorber or a combination of these materials with the appropriated absorbance characteristics. Said anode and cathode are connected to the charging mechanism of the electronic device, situated in the device body 110, through wires 117 and 111 respectively. As exemplified in the drawing, a high-energy photon beam 210 can penetrate the layers above the active layer, be absorbed by the active layer and generate photocurrent. Visible light, however, such as beam 220, which possesses higher wavelengths than the maximal absorbance of the active layer, can pass through the solar cell freely. The detached structure is presented for illustration purposes; all layers should be adjacent in the final product.

What is claimed is:

1. A mobile electronic device with high-energy photon solar recharging functionality comprising at least:
a. a display module, capable of displaying the screen's graphics;
b. a solar cell comprising at least:
i. an anode comprising a transparent electrode layer;
ii. a photoactive layer with an average of absorption coefficients in the wavelength range of 500 nm to 800 nm which is smaller than 30% of the average of absorption coefficients of the material in the range of 350 nm and 500 nm. Said averages are calculated over the measurements in round nanometer values and 1 nm increments;
iii. a cathode comprising a transparent electrode layer; and
c. a charging mechanism capable of recharging the batteries of the device.
Wherein said solar cell is positioned in front of the display module, towards the outer surface of the screen, and electrically connected to the charging mechanism of the device.

2. The mobile electronic device according to claim 1, wherein the device's solar cell photoactive layer is composed of high band gap semiconductor, with a gap energy value larger than 2.47 eV.

3. The mobile electronic device according to claim 1, wherein the device's solar cell photoactive layer is composed of at least 70% of the materials or a blend of the materials in the group of: Cr₂O₃; MnO; CoO; TiO₂; NiO; As₂S₃; ZnSe; ZnS; ZnO; Ge₃N₄; WO₃; BCN; GaN; SrTiO₃; C₃N₄; Bi₂WO₆ and SiC, and the material possesses in addition a band gap larger than 2.58 eV.

4. The mobile electronic device according to claim 1, wherein the device's solar cell photoactive layer is composed of particles falling under the categories of quantum dots or nano-rods. In addition, the material possesses a band gap with a value larger than 2.47 eV.

5. The mobile electronic device according to claim 1, wherein the device's solar cell is an organic solar cell.

6. The mobile electronic device according to claims 1 through 5, wherein the solar cell is designed comprising an additional electron transport layer or hole transport layer or both of the layers.

7. The mobile electronic device according to claims 1 through 6, wherein the mobile device belongs to the following group: smartphone; laptop computer; tablet; e-reader and mobile phone.

8. The devices according to claims 1 through 7, wherein the device's solar cell contains more than one photoactive layer, in a tandem or multijunction configuration.
